(19) United States
(12) Patent Application Publication
(10) Pub. No.: US 2013/0178011 A1
(43) Pub. Date: Jul. 11, 2013

(54) DOPANT COMPOSITIONS AND THE METHOD OF MAKING TO FORM DOPED REGIONS IN SEMICONDUCTOR MATERIALS

(71) Applicants: David S. Ginley, Evergreen, CO (US); Calvin J. Curtis, Lakewood, CO (US); Marinus Franciscus Antonius Maria van Hest, Lakewood, CO (US); Heather A. S. Platt, Golden, CO (US); Alexander Miedaner, Boulder, CO (US); David E. Carlson, Williamsburg, VA (US); Murry S. Bennett, Frederick, MD (US); Wensheng Ren, Denver, CO (US)

(72) Inventors: David S. Ginley, Evergreen, CO (US); Calvin J. Curtis, Lakewood, CO (US); Marinus Franciscus Antonius Maria van Hest, Lakewood, CO (US); Heather A. S. Platt, Golden, CO (US); Alexander Miedaner, Boulder, CO (US); David E. Carlson, Williamsburg, VA (US); Murry S. Bennett, Frederick, MD (US); Wensheng Ren, Denver, CO (US)

(73) Assignee: ALLIANCE FOR SUSTAINABLE ENERGY, LLC, Golden, CO (US)

(21) Appl. No.: 13/598,170

(22) Filed: Aug. 29, 2012

Related U.S. Application Data
(60) Provisional application No. 61/528,316, filed on Aug. 29, 2011.

(51) Int. Cl. H01L 31/18

(52) U.S. Cl. CPC H01L 31/18
USPC 438/98; 438/57; 252/500

(57) ABSTRACT

Dopant compositions comprising a semiconductor material are described. Examples of dopant compositions comprise a particulate dopant component and a liquid or paste component, or comprise a dopant component and a particulate silicon component. Methods of forming doped regions in a semiconductor substrate material using the dopant compositions are described. A dopant composition including a dopant particulate component is described as a dopant source in a method for the formation of radiation-fired or radiation-doped contacts, for example in the formation of laser-fired or laser-doped contacts. Examples of the method find application in relation to the manufacture of photovoltaic cells. The use of doped particulate material, for example a composition including doped silicon powder, may reduce the likelihood of damage to the substrate.

### CROSS-REFERENCE TO RELATED APPLICATIONS

This application claims priority to U.S. Provisional Patent Application No. 61/528,316 filed Aug. 29, 2011, which is incorporated herein by reference in its entirety.

### CONTRACTUAL ORIGIN

The United States Government has rights in this invention under Contract No. DE-AC36-08GO28308 between the United States Department of Energy and the Alliance for Sustainable Energy, LLC, the Manager and Operator of the National Renewable Energy Laboratory.

### BACKGROUND

Photovoltaic cells are devices, which are used for the conversion of light energy into electrical energy. For solar cells, the light incident on the cell is sunlight. Known photovoltaic cells include a semiconductor portion, generally comprising silicon comprising regions of n-type (e.g. phosphorus-doped) and p-type (e.g. boron-doped) semiconductor which provide an emitter and base in the device. The base and emitter are such that when light is incident on the cell, positive and negative charge carriers are formed which are separated from each other at the junction between the n- and p-type regions. Electrically conductive elements connected to the emitter and to the base are used to carry the separated charge carriers from the emitter and base regions.

Photovoltaic cells are conventionally made using silicon wafers, which commonly comprise a p-type silicon wafer. In a known method, a surface of the wafer is doped to form an n-type layer; such doping may for example be carried out by applying a phosphoric acid coating to the wafer at elevated temperature, for example 800 to 900 degrees C. Electrical contacts are then applied to the front and rear surfaces of the device (the n and p surfaces) to enable the photo-generated current to be carried from the cell. For the surface onto which the light is to be incident, the contact is commonly applied in the form of a grid to allow light to reach the semiconductor surface. If a n-type silicon wafer is used, then a surface of the wafer is doped to form a p-type layer. Such doping may for example be carried out by exposing a surface to a boron source at elevated temperatures of about 900 to 1050 degrees C. This may be accomplished by applying a boron diffusion mask to one side of the wafer and then exposing the wafer to a gas such as BBr₃ for about 30 minutes at 1000° C.

A method for the manufacture of such a photovoltaic cell typically includes the application of a surface coating on the semiconductor material. For example, a layer of silicon nitride or silicon dioxide may be applied to a surface of the semiconductor material as an antireflection coating. The coating material may form an antireflection layer on the device which can improve passage of light, in particular light having a desirable wavelength characteristic, into the device. The coating comprises a dielectric material and forms a passivation layer on the semiconductor material, for example to reduce unwanted recombination of charge carriers at the surface of the device. This can be accomplished for example by using passivation layers such as amorphous silicon (a-Si:H), which can in some cases remove defect states at the surface by passivating the defect states with hydrogen (chemical passivation). Other passivation layers such as silicon nitride and aluminum oxide may contain a large density of fixed charges which may cause band bending (a local electric field) which may prevent one of the carriers (either electrons or holes) from reaching the surface and recombining.

For the fabrication of a device including a coating layer for example a dielectric layer, it is necessary to form the doped base and/or emitter regions on the semiconductor surface, and also to form the electrical contact with the base and/or emitter regions. U.S. Pat. No. 6,982,218 describes a method in which a doping material is applied to a semiconductor surface. Subsequently a dielectric coating is applied to the whole surface of the semiconductor material, the coating being subsequently etched to remove regions of it, the electrical contacts being applied at the removed regions. In a further method described, a semiconductor material including a doped base region is coated with a dielectric passivation layer. A metal layer, for example including aluminum, is applied over the dielectric passivation layer, for example by vapor deposition or sputtering. Radiation, for example laser radiation, is subsequently applied to regions of the surface to effect localized melting of the components. A localized molten mixture is said to be formed between the layers such that, after resolidification, an electrical contact is formed between the semiconductor and the metal layer. However, it is considered that both of these methods can lead to undesirable damage to the silicon and/or other components in the region of the heating or etching.

US2008/0026550 describes a method by which it is stated that a semiconductor material can be doped using a laser doping technique to form an emitter. According to a method described, a dopant material is applied to a surface, for example a surface of a silicon wafer or an interlayer which may be configured as a passivation layer for passivating the surface of a semiconductor material. The dopant medium may be deposited by spin coating or by screen or film printing or by using a multi-stage sputtering technique. The dopant medium is a solid coating where the medium is first deposited on a starting substrate which subsequently acts as a sputtering target. The medium can consist of the dopant material and can be deposited in the form of a powder on the starting substrate. Then the medium can be sputtered from the starting substrate onto an intertarget (which is a substrate that subsequently acts as another sputtering target). Then the medium on the intertarget can be sputtered onto the solid state material (e.g. a silicon wafer) to be doped. Then, by beaming with laser pulses, a region of the solid-state material below the surface contacted by the dopant material is melted so that the dopant is said to diffuse into the melted region and to recrystallise during cooling of the melted region thereby forming an emitter region. However, it is considered that this method is complicated and involves too many processing steps. Moreover, the sputtering process can lead to undesirable damage to the silicon and/or other components in regions adjacent to the application of the laser pulses.

It would be desirable to provide a method of production of a photovoltaic cell which overcomes or mitigates one or more of the problems of the methods described above, and/or other problems, or to provide an alternative method for use in fabricating a photovoltaic cell.

The foregoing examples of the related art and limitations related therewith are intended to be illustrative and not exclusive. Other limitations of the related art will become apparent to those of skill in the art upon a reading of the specification and a study of the drawings.

### SUMMARY

The following embodiments and aspects thereof are described and illustrated in conjunction with systems, tools and methods that are meant to be exemplary and illustrative, not limiting in scope. In various embodiments, one or more of the above-described problems have been reduced or eliminated, while other embodiments are directed to other improvements.

Dopant compositions, such as exemplary embodiments related to dopant silicon compositions, have been developed that can be patterned on semiconductor material or photovoltaic cells by the forming of a doped region, as well as the forming of base and/or emitter regions, in a semiconductor material. Exemplary methods described herein also are related to how to process these dopants. The dopants and process can be used to make high performance semiconductor materials, such as solar cells, at low cost and at relatively low temperatures using only a few process steps.

In addition to the exemplary aspects and embodiments described above, further aspects and embodiments will become apparent by reference to the drawings and by study of the following descriptions.

### BRIEF DESCRIPTION OF THE DRAWINGS

Exemplary embodiments are illustrated in referenced figures of the drawings. It is intended that the embodiments and figures disclosed herein are to be considered illustrative rather than limiting.

FIG. 1 shows the concentration of boron dopant at different depths for a laser-fired contact.

FIG. 2 shows schematically a sectional view of an array of contacts formed on a Si wafer using a laser processing method.

FIG. 3 shows a process flow for an example in which laser doping is used to form a back-contact solar cell.

FIG. 4 shows schematically an example of an array of contacts formed on a Si wafer using a laser processing method shown in FIG. 3.

### DETAILED DESCRIPTION

Aspects of the present disclosure provide a dopant composition. This disclosure describes that the dopant composition can for example be used in a method of production of a base or emitter contact, for example for a photovoltaic cell.

Exemplary embodiments include a method of forming a doped region in a substrate comprising a semiconductor material, the substrate including a dielectric layer over at least a portion of the semiconductor material, the method comprising the steps of: applying a dopant composition to a region of the dielectric layer, the dopant composition including a particulate component; and treating the applied dopant composition with radiation to form a doped region in the semiconductor material.

In some examples, the dopant composition may include a dopant particulate component. In other examples, the dopant composition may comprise for example a mixture of a dopant material and a particulate material, such as silicon. In such cases, the dopant may be for example a liquid or powder. Where reference is made herein to particulate material, in some examples, the material may be in the form of a powder. The powder may be combined or incorporated with other components in some examples to form the dopant composition.

The step of treating with radiation comprises applying laser radiation to the applied dopant composition. During the application of the radiation to the doped composition, at least a portion of the applied dopant component passes through the dielectric layer into the semiconductor material to form the doped region. It has been identified that the use of a dopant composition including a particulate component, can be advantageous as a dopant source in the formation of radiation-fired or radiation-doped contacts. The formation of laser-fired or laser-doped contacts may also be implemented. In some examples, the dopant compositions including particulate component, may have relatively low cost compared with conventional dopant compositions. In addition, the use of doped particulate material, for example doped silicon particulate, is thought to reduce the likelihood of damage to the substrate.

Further embodiments describe a dopant component that may be mixed with a conductive material, for example a conductive paste or ink. The resulting conductive dopant may then be applied to a region of the dielectric layer, and the applied dopant composition is treated with radiation.

The exemplary dopant compositions described herein may be used to form a doped region in a semiconductor material. An exemplary method of forming a doped region in a substrate comprising a semiconductor material, the substrate including a dielectric layer over at least a portion of the semiconductor material, the method comprising the steps of: applying a dopant composition to a region of the dielectric layer, the dopant composition comprising a dopant component and a conductive material component, and treating the applied dopant composition with radiation to form a doped region in the semiconductor material. Thus in some examples of the disclosure, the dopant component includes an electrically conductive material component. As described further herein, the electrically conductive material component can form an electrical contact to the doped region of the substrate. During the application of the radiation to the conductive material-dopant composition, at least portions of the conductive material and the dopant components pass through the dielectric layer into the semiconductor material to form both the doped region and a conductive contact to the doped region. The conductive material component may comprise a metal component. During the application of the radiation to the metal-dopant composition, at least portions of the metal and dopant components pass through the dielectric layer into the semiconductor material to form both the doped region and a metal contact to the doped region. Thus, the use of a dopant composition comprising a conductive paste or ink has the advantage of being able to simultaneously form both a doped region and a metal electrical contact to the doped region.

Further exemplary embodiments describe a layer of an electrically conductive material, for example including a metal may be deposited over the applied dopant composition containing particles of dopant material. An exemplary metal may include silver. The radiation treatment may then be used to form the contact. For example, the contact may be formed by laser firing the metal and the dopant through the dielectric layer to the semiconductor material.

In some embodiments described herein, the substrate includes a passivation layer over at least a portion of the semiconductor material. The exemplary method comprises the steps of: applying a dopant composition to a region of the passivation layer, the dopant composition comprising a particulate dopant component or a mixture of a silicon particulate and a dopant component; and laser processing the dopant composition applied to the substrate to form a doped region in the semiconductor material. The passivation layer may include a dielectric material.

The substrate may for example include a coating layer, which may for example be a passivation layer and/or an antireflective layer and/or provide other functionality. The coating layer may have any appropriate composition. For example, the coating layer may comprise silicon dioxide, aluminum oxide, silicon nitride, titanium dioxide or other material. The coating layer may include more than one material. In contrast to currently known methods of forming radiation-processed contacts by laser-firing a dopant metal, for example aluminum, through a dielectric material such as SiNₓ or SiO₂, where localized p⁺ contacts are formed, in examples of the present disclosure, localized n⁺ contacts can be formed by using dopant compositions comprising a powder of an n-type dopant (e.g. Sb or Sb₂0₃). Moreover, since silver contacts are widely used in solar cells, the contact may be formed in some examples by applying the dopant composition and then overcoating with a silver paste or ink and forming a contact by laser firing the metal and the dopant through the dielectric layer to the semiconductor material.

For the case of a dopant composition comprising a conductive paste or ink, or a mixture of dopant and powder, like silicon, the dopant component may be any appropriate material including a source of the dopant. The dopant component may be in liquid or solid form in the dopant composition. In the fabrication of the dopant composition, the dopant component may be added to the conductive paste or to the component in any appropriate form, for example liquid or solid (for example as a dopant powder). The dopant composition comprising a conductive paste or ink can be prepared for example by adding a dopant to a solution or slurry of the conductive ink or by mixing a dopant powder with the conductive paste while a dopant—such as a silicon powder composition—can be prepared for example by adding a dopant to a solution or slurry of silicon powder or by mixing a dopant powder with a silicon powder. Other methods may be used as appropriate. It will be understood that the dopant composition may include additional components to the dopant and conductive paste or ink or to the dopant and silicon components such as an inorganic or organic binder to provide adhesion and mechanical durability.

In some cases, the dopant composition applied to the substrate further comprises a liquid medium. For example, the dopant composition may be applied to the substrate in powder form, or may be applied with a liquid carrier medium. For example, the liquid carrier may comprise water, alcohol, ethylene glycol, or other component or mixture of components. The dopant composition may comprise a solution containing the doped powder. In some applications the carrier will be removed from the composition after application to the substrate before the radiation treatment. For example, the carrier may be a material which evaporates, for example at ambient temperature, or at an elevated temperature of for example above 100 degrees C. Alternatively or in addition, material may be removed using a physical or chemical method after the radiation treatment.

In some cases, a binder may be added to the dopant composition to provide improved adhesion and improved mechanical properties. The binder may for example comprise organic molecules that are volatilized by processing at an elevated temperature and/or inorganic molecules that do not readily volatize, but for example provide mechanical durability. In other cases, a silicon powder may be added to the dopant composition, for example to improve the efficiency of the laser doping process. When a laser beam is incident on a silicon surface covered with a dopant source, the surface temperature may increase to more than 2000 C. In the case of dopant sources such as an antimony powder, the high surface temperature may cause much of the antimony to evaporate before it is able to diffuse into the molten silicon surface. If the antimony is mixed with a silicon powder, then the evaporation of the antimony may be suppressed and more of the antimony may diffuse into the silicon wafer. A mask may also be used so that the dopant material can be applied to a particular region or regions of the substrate.

The dopant composition is printed onto the substrate. Any appropriate printing technique may be used. For example, the printing may use an aerosol jet printing or spraying technique. The dopant composition may be applied using ink jet printing or screen printing. In examples, a gas may be used to assist the flow of ink during an aerosol jet printing operation. For example, a central flow of ink surrounded by a circular sheath of Argon gas may be formed giving narrow lines of printed material while the printing nozzle is shielded from the ink by the gas. Ultrasonic energy may be applied to the printhead region of an aerosol jet printer to assist printing. By using ultrasonics, the printer may be used to print relatively large particles, for example up to 200 microns in diameter. The exemplary method includes applying the dopant composition to a plurality of discrete regions on the substrate. By the use of a mask and/or printing techniques, and/or other method, an array or pattern of dopant composition regions can be deposited on the substrate. An array or pattern of doped regions of the semiconductor material can be formed. An array or pattern of emitter and/or base contacts can be formed in the semiconductor material. By using particular printing techniques, or masking or other techniques, the dopant composition can be relatively accurately applied to discrete areas on the substrate surface. In this way, deposition of the dopant composition can be restricted to predetermined regions of the substrate. Efficient use of the dopant material can be enabled, in which the dopant material is applied to those regions of the substrate at which the base, emitter or other doped region is to be formed in the semiconductor material.

An exemplary method further describes including the step of using a printing apparatus to deposit a dopant composition at a plurality of discrete regions of the substrate and a method of forming a plurality of doped regions in a substrate including a semiconductor material. Deposited dopant composition may subsequently be subjected to a treatment, for example radiation treatment, to form a plurality of doped regions in the semiconductor material. The dopant composition may comprise the dopant substantially alone such as fine powders of boron, aluminum, indium, antimony or bismuth or in compounds such as boric acid, boron anhydride, aluminum hydroxide, antimony trioxide, for example. This aspect may include one or more further features of other aspects described herein, as appropriate. Depending on the type of doped region to be formed in the semiconductor material, the dopant component may comprise n or p-type dopants.

The exemplary methods described herein may also include applying a first dopant composition to a first region of the substrate, and applying a second dopant composition to a second region of the substrate. In this way, two (or more) different types of doped region may be formed on the substrate. After appropriate treatment, for example radiation treatment, thus two (or more) different types of doped region may be formed in the semiconducting material. The first and second dopant compositions may comprise p- and n-type dopants, respectively. The method may include applying the first dopant composition to a plurality of first regions to form a first array of first dopant regions on the substrate, and applying the second dopant composition to a plurality of second regions to form a second array of second dopant regions on the substrate, and treating the first and second regions to form first and second arrays of doped regions in the semiconducting material.

The order of method steps used may be chosen as appropriate. For example, the first and second regions might be deposited on the substrate during the same operation, for example co-printed using a printer including printer nozzles for printing the first dopant composition and printer nozzles for printing the second dopant composition. Alternatively, one set of dopant regions could be printed after the other is complete. The treatment of the first and second regions could be carried out in a single operation, or for example after the deposition of the first regions before deposition of the second regions. Other implementations are possible.

The doped region of the semiconductor material formed by a method described herein forms a base or emitter contact. By the methods described above therefore, an array of base and emitter contacts can be formed on a substrate. In cases where a silicon powder is used, the average primary particle size of the silicon component may be less than 600 nm, for example about 400 nm or less. In some examples, the average secondary particle size of the silicon component is less than 2 microns. In some examples, the particle size is about 1 micron or less. The silicon may have a primary average particle diameter of between about 10 and 100 nm.

The average primary particle size of the dopant composition is less than 300 nm, for example about 200 nm or less. In some examples, the average secondary particle size of the dopant composition is less than 2 microns. In some examples, the particle size is about 1 micron or less. The dopant composition may have a primary average particle diameter of between about 10 and 100 nm. From the BET surface area measurement known by the skilled person, the primary particle diameter of the sample can be calculated for example using the following equation:

Specific surface area=(6×10³)/pd

where p=the specific gravity of the powder material in g/cc and d=particle diameter in 10 mm.

As will be appreciated by the skilled person, in practical cases, primary particles in the dopant composition and/or in for example the silicon powder, where present, further aggregate to exhibit the secondary particle structure of a few to 100 or more particles. The size of the particles in the dopant composition as measured may include the size of secondary particles. The primary particle size is the lower limit of the particle size for a particular sample of the dopant composition. The secondary particle size within a dopant composition liquid dispersion may be measured for example by dynamic light scattering. Suitable particle size analyzers include for example Microtrac UPA apparatus of Honeywell.

The dopant composition particulate, for example the silicon powder, if present would be in the form of ultra fine primary particles. The dopant composition includes a source of a Group V or Group III element. The dopant composition may include the dopant element itself and/or may include a source of the dopant. The dopant may include Sb or B, for example as a powder. Thus the Sb or B may be present in the form of particles in the dopant composition. The dopant composition may include a compound containing the dopant such as Sb₂0₃, Al(OH)₃, H₃B0₃ or B₂O₃. The method may further include the step of preparing the dopant composition, including forming a mixture of powder particles, leaving the mixture for a period for settling, and separating relatively small powder particles from the mixture of relatively larger settled powder particles. Surfactants can be added to control the particle size distribution.

The treatment with radiation may comprise applying laser radiation to the applied dopant composition on the substrate. Other methods may be used to treat the applied doped composition as appropriate. For example, other radiation may be used, for example infra-red radiation, or UV radiation. The radiation is applied using a focused source of radiation, such that the radiation can be directed to the region of the substrate to be treated.

Laser processing may be used to form the doped semiconductor region. The treatment may include using a laser to laser-dope the surface region of a silicon wafer. The laser radiation source may comprise a high speed scanning laser. In examples, the laser operation is such that the region to be treated is treated in less than about 1 second. The laser beam can for example be scanned using galvo mirrors, for example at speeds of about 10 m/s. In some examples, the beam may be split into multiple beams to obtain higher throughput. In some examples, the laser is focused to produce a beam having a diameter less than 200 microns. In other examples, the diameter is about 100 microns or less. In this way, a beam can be provided having a high power density. When this high power density beam hits the substrate surface, it creates a localized hot laser spot where the substrate material becomes a high temperature solid, or molten or gaseous or even in some cases plasma depending on the amount of laser energy delivered to and absorbed by the substrate surface. In this high temperature environment, the dopant atoms will diffuse into the substrate, forming a local highly doped area.

Without wishing to be bound by any particular theory, it is thought that in some cases, a high energy laser pulse will melt and vaporize the powder or particulate component of the dopant composition, for example the dopant powder, the dielectric passivation layer (if present) and some of the Si wafer and may eject a plume of evaporated material from the surface creating a crater in the substrate. It is thought that the plume involves a shock wave at a high local pressure, and many of the atoms and molecules in the plume subsequently return to the surface as the high pressure region relaxes. The plume recoil may occur only a few tens of nanoseconds after the laser pulse ends, and since the silicon remaining in the crater will typically stay molten for a few hundred nanoseconds (depending on the laser power), the dopant returning in the plume recoil will in many cases diffuse rapidly into the molten Si.

The method may further include applying an electrically conductive material to the doped region in the semiconductor material. The method further includes forming a contact on the doped region formed. The contact may be applied by any appropriate method, for example by printing a conductive material over the laser-processed contact.

The method may further include applying a plurality of fingers of conductive material. Where a plurality of doped regions has been formed, a plurality of contacts is applied for connecting the regions. More than one set of contacts may be applied, in particular where both n- and p-doped regions have been formed, for example to form both base and emitter contacts. For example, sets of interdigitated fingers of conductive material may be applied. The contacts may comprise any appropriate material, for example silver. Bus bars are also formed, for example by printing, to connect the contacts. The method may include applying an electrically conductive material to the dopant composition on the substrate prior to the radiation treatment.

The disclosure further describes a method of forming a doped electrical contact in a substrate comprising a semiconductor material, the substrate including a dielectric layer over at least a portion of the semiconductor material, the method comprising the steps of: applying a dopant composition to a region of the dielectric layer, the dopant composition comprising a particulate component; applying an electrically conductive material to the region of the dielectric layer, and treating the applied conductive material and dopant composition with radiation to form the doped electrical contact in the semiconductor material.

The treatment comprises radiation processing, such as laser processing or example laser firing. In some examples, the electrically conductive material is applied over a portion of the applied dopant composition. Thus in some examples, the dopant composition is applied first to the dielectric layer, the electrically conductive material being applied subsequently.

In examples described in which a dopant composition is applied to a plurality of regions of the dielectric layer, the electrically conductive material may be applied to those regions, or to a sub-set of those regions. In this way, on the radiation treatment, for example laser-firing, the dopant and metal are fired into the substrate. Thus there are at least two options for forming base/emitter contacts on passivated semiconductor substrates by laser processing. The first method, laser doping, consists of the steps of applying dopant material to the substrate surface first, laser processing the dopant into the substrate and subsequent deposition of the contact metal. The other, laser firing includes the steps of applying dopant material and depositing contact metals on the substrate surface, and then laser firing the dopant and metal into the substrate. In some examples, the contact metal may be applied to the surface together with the dopant material in a dopant composition including a metal component.

It has been found that in some cases the electrical resistance of contacts formed by laser doping could increase rapidly if the laser processed contacts were treated at high temperature (for example above 200 degrees C.) while contacts formed by laser firing had better thermal stability in some cases compared with the laser doping method, but required the application of the two layers of materials to the substrate prior to the laser firing. It would be desirable to provide a method of forming the contacts which reduced those or other problems, or an alternative method. The dopant composition may further comprise an electrically conductive component. Thus according to this feature, the conductive material can be applied to the substrate together with the dopant, the base or emitter contact being formed by the radiation treatment.

This disclosure further describes a method of forming a base or emitter contact in a substrate comprising a semiconductor material, the method comprising the steps of applying a dopant composition to a region of the substrate, the dopant composition comprising a dopant component, an electrically conductive component; and treating the applied dopant composition with radiation to form a base or emitter contact in the semiconductor material.

The treating step may further include an annealing step. The annealing may for example include heating at elevated temperature to form the electrical contact, for example at about 350 degrees C. The treating with radiation comprises application of laser. When the radiation beam, for example laser beam, hits the substrate surface, it creates a localized hot laser spot where the substrate material becomes a high temperature solid, or molten or gaseous or even in some cases plasma depending on the amount of laser energy delivered to and absorbed by the substrate surface. In this high temperature environment, the dopant atoms will diffuse into the substrate, forming a local highly doped area, and the metal material will mix with the substrate material forming a conductive compound if the conductive material is applied before the laser processing step. It has been recognized that by use of a dopant composition including both the dopant and the conductive material, it may be possible to form an effective interface layer by laser treatment which is able to connect both to the cell semiconductor body and to the cell electrode at an acceptable electrical resistance. The dopant composition may for example be in the form of an ink or a paste or any other appropriate form.

By use of this procedure, the forming of the base/emitter contacts might be simplified because only one step is required to apply both the dopant and the contact material simultaneously instead of by two steps as required by other methods. By using such a procedure in the forming of a photovoltaic cell, it is anticipated that manufacture will be simplified and that low resistant electrical contacts to the PV cell can be obtained. The electrically conductive material may comprise for example a metal.

Examples of metals which could be used as additives to the dopant composition include Ag, Al, Ni, Cu. The electrically conductive component may include more than one electrically conductive material. It has been found that low resistance contacts can be formed using such a dopant composition.

The dopant composition may further include a semiconductor material, for example Si powder or particulate material as described herein. Features described herein in relation to other aspects may be applied to this aspect. The substrate comprises a silicon wafer. Examples of this disclosure find application in relation to substrates of other composition. The silicon wafer may include a coating, for example a dielectric passivation layer. For example, at least one surface of the silicon wafer may be coated with silicon nitride. The silicon wafer may include a surface texture on at least one surface. In some examples, a surface texture where provided is provided at the front surface of the wafer. The textured surface may in such cases be combined with an antireflection coating to maximize light coupling into the solar cell. For back-contact solar cells, the back surface would not usually be textured since texture can interfere with laser processing making it difficult to obtain a high quality laser-processed contact in some cases. Also, in the case of back-contact cells, the minority carrier lifetime of an n-type silicon wafer is in some examples greater than about 200 microseconds for a 150 micron thick wafer so that the diffusion length is about 3× the wafer thickness. For a p-type silicon wafer, the lifetime is greater than about 66 microseconds (the mobility of electrons is about 3× the mobility of holes, and the diffusion length is related to the product of the lifetime and the mobility).

This disclosure further describes a base or emitter contact in a semiconductor material, the contact being made by a method including steps described herein. This disclosure further describes a photovoltaic cell fabricated by a method including steps described herein. This disclosure further describes an apparatus for carrying out steps of a method described herein. The disclosure further describes a dopant composition for use in a method including steps as described herein. An exemplary embodiment provides a dopant composition for forming a doped region in a substrate comprising a semiconductor material, the dopant composition comprising a particulate component and an additional component. The dopant composition is in some applications described in this disclosure suitable for forming a doped region in a semiconductor material by laser processing, for example laser-firing or laser doping. The particulate component may comprise a dopant material. The particulate component may be a material other than a dopant material, for example a particulate silicon component, the dopant material mixed with the particulate component in the form for example of a liquid or powder. The dopant composition may include a mixture of dopant and silicon particulates. In cases involving a silicon particulate, the dopant composition may further include a liquid medium. The dopant composition may for example comprise a solution containing doped silicon particulate. The dopant composition may comprise only particulates of a dopant such as boron, aluminum, indium, antimony or bismuth.

Depending on the type of doped region to be formed in the semiconductor material, the dopant component may comprise n or p-type dopants. The average primary particle size of the dopant composition may be less than 600 nm, for example about 400 nm or less. The average secondary particle size may be less than 2 microns, or in some cases, about 1 micron or less. The average primary particle size may be less than 600 nm, for example about 400 nm or less. The average primary particle size may be between about 10 and 100 nm. Where reference is made herein to particular particle sizes, for example average particle sizes, the particle size distribution is to be determined on the basis of wt. The dopant composition includes a source of a Group V or Group III element. The dopant composition may include a range between 20-50% by weight, at least 50% by weight, at least 20% by weight, or in some cases, at least 1% by weight of the dopant. Another exemplary embodiments is a dopant composition comprising a particulate dopant component and a liquid or paste component. In some examples, the dopant composition includes a semiconductor component, which may for example comprise silicon. The dopant composition may include particles of semiconductor component. In some examples, the dopant composition comprises a particulate silicon component. The liquid or paste component may comprise a solvent. It may include one or more of water and an organic solvent. The organic solvent may comprise one or more of polyvinylalcohol and ethylene glycol. The dopant composition may include ethyl cellulose. The average primary particle size of particles of the dopant composition may be 10 less than 600 nm, for example about 400 nm or less. The average secondary particle size of particles of the dopant composition may be less than 2 microns, or in some cases, about 1 micron or less. The average primary particle size of particles of the dopant composition may be for example between about 10 and 100 nm. In cases where the dopant composition includes at least 50% by weight, or in some cases, at least 1% by weight of the dopant, the dopant source includes a Group V or Group III element. The dopant component may comprise a source of one or more of the group consisting of P, As, Sb, Bi, B, Al, Ga and In. The dopant composition may further include one or more of a surfactant, a dispersant and a wetting agent.

Another exemplary embodiment is a dopant composition comprising a particulate dopant component. The dopant composition may further comprise a solvent, for example one or more of water and an organic solvent. The average primary particle size of particles of the dopant composition and/or the dopant component may be less than 600 nm, for example about 400 nm or less. The average secondary particle size of particles of the dopant composition and/or the dopant component may be less than 2 microns, or in some cases, about 1 micron or less. The average primary particle size of particles of the dopant composition may be between about 10 and 100 nm. The dopant composition may include a range between 20-70% by weight, at least 50% by weight, or in some cases, at least 70% by weight of the dopant component. The dopant component may include a source of a Group V or Group III element. The dopant component may comprise a source of one or more of the group consisting of P, As, Sb, Bi, B, Al, Ga and In. The dopant composition may further include a particulate semiconductor component. The exemplary embodiment further provides a dopant composition comprising a dopant component and a particulate semiconductor component. The semiconductor component may comprise silicon. The dopant composition may comprise particles of dopant component.

Another exemplary embodiment is powder dopant composition including any appropriate combination of features of the composition described herein. Alternatively, the dopant composition may be in the form of an ink or a paste. A method of preparing a dopant composition provided by the exemplary embodiment includes the step of mixing a powder dopant component with a liquid or paste component.

This disclosure also describes use of a dopant composition as described herein in a method of forming a doped region in a substrate comprising a semiconductor material. This disclosure further describes the use of a particulate dopant in a method of forming a doped region in a substrate comprising a semiconductor material. Also described by this disclosure is a method of forming a doped region in a substrate comprising a semiconductor material, the method including the steps of applying a dopant composition to a surface of the substrate, the dopant composition including a particulate dopant component. The dopant composition may include one or more further features as described herein in relation to any other embodiment, as appropriate. This disclosure describes that the dopant composition may further comprise an electrically conductive component. As discussed herein, by including a conductive material in the dopant composition applied to the substrate, the contact can be formed in fewer steps than otherwise if for example the conductive material were applied after the doped substrate region had already been formed.

This disclosure further describes a dopant composition for use in forming a base or emitter contact in a substrate comprising a semiconductor material, the composition comprising a dopant component and an electrically conductive component. The dopant composition could also comprise a dopant component, a silicon particulate component and an electrically conductive component. The dopant composition may be in the form of an ink or a paste. In some examples, the electrically conductive component comprises a metal. For example, the metal comprises one or more of Ag, Al, Ni and Cu.

It has been found that by using the dopant and electrical components together in a dopant composition, a connection between the semiconductor material and the cell electrode can be formed at an appropriate resistance. For example, the specific contact resistivity of the contact formed is <10 mΩ-cm². This disclosure describes a composition, for example an ink or paste, containing two functional components: the dopant material, and the conductive material. The dopant material may be n- or p-type. N-type materials may include for example P, As, Sb, Bi. P-type may include for example B, Al, Ga, In. The conductive material may include for example Ag, Al, Ni or Cu and/or other metals.

The composition may also include other components, for example additives to modify mechanical and/or chemical properties. For example, an inorganic or organic binder may be included to improve adhesion and mechanical durability. In methods described herein, the dopant/conductive material composition is applied to the substrate surface prior to treatment, for example laser processing. Without wishing to be bound to any particular theory, it is thought that during processing, for example laser firing, the dopant and the metal are diffused into the molten substrate forming a conductive interface layer at high temperature under laser firing. The diffused dopants can facilitate moving current from the substrate to the conductive interface layer, and the alloy of metal and substrate may bridge the interface layer to the metal cell electrode. Both materials in the dopant composition after laser firing play important roles to make a good electrical connection from for example the solar cell electrode to the solar cell body and may form a stable, low resistant contact to the solar cell.

The dopant composition may further include a silicon particulate component. The dopant composition may comprise a liquid medium. The average primary particle size of the dopant composition may be less than 600 nm, for example about 400 nm or less. The average secondary particle size may be less than 2 microns, in some cases about 1 micron or less. The dopant composition may include in a range between 20-50% by weight, at least 50% by weight, in some cases at least 1% by weight of the dopant. The electrically conductive component may be included in a range between 20-100% by weight, at least 99% by weight, in some cases at least 50% by weight of the dopant composition. The desired ratio of the dopant material to the metal material in the composition is not fixed. It is thought that the ratio will depend on for example the laser-processing conditions and/or on the diffusivities of the dopant and metal atoms in molten or liquid silicon. The consideration of the relative ratio of dopant material to metal material is not based on absolute number of atoms but rather on the actual physical effect it produces. For example, the number of metal atoms may be significantly higher near the surface than the dopant atoms depending on the laser-processing conditions and the diffusivities of the dopant and metal atoms in the molten silicon. Thus, for example, the metal concentration in the silicon after laser processing might be relatively high (for example about 10²¹ atoms/cm³) and localized near the surface while the dopant atom concentration might be only about 10¹⁸ atoms/cm³ but extend deeper into the silicon wafer due to a higher diffusivity in molten silicon than the metal.

Where the composition is for use in the fabrication of a solar cell for example as described in this disclosure, the selection of metal material for the composition may be based on the choice of desired conductive material for the electrode grid of the solar cell. If the contact to the cell and the electrode grid of the cell are made simultaneously in a single process, then the desired conductive metal material for electrode grid, such as for example Ag, Al, Ni, or Cu, would be at high concentration level in the composition (greater than 90% by weight for some examples). If the contact to the cell and the electrode grid of the cell are made separately in a two step process, then using the same metal material for the ink/paste ingredient and the electrode grid may be considered a logical choice. However the use of different metal materials is possible, for example if the bonding of selected electrode metal material to the ink/paste metal material is strong. Also, a paste containing a dopant and the metal Ni might for example be used in conjunction with laser processing conditions that lead to the formation of a nickel silicide at the surface of the laser processed region. In this case, Cu might be used as a grid electrode since the nickel silicide would act as barrier to Cu diffusion into the silicon.

Examples of this disclosure can form high quality n⁺ and p⁺ contacts in crystalline silicon by laser processing a dopant composition comprising a dopant particulate or a silicon particulate comprising a dopant composition through a dielectric passivation layer. The process can be used to make high performance solar cells at low cost and at relatively low temperatures using only a few process steps. Examples described herein may overcome the limitation of laser-induced damage in the formation of laser-fired contacts. Examples described herein can be used to produce low-cost cells. This disclosure describes that the method of fabrication of the doped regions may be carried out at relatively low temperature, for example at room temperature. The method is carried out as a non-contact method. This disclosure describes that examples may be applied to the forming of emitter and/or base contacts for solar cells. For example, features described may be used to form emitter and/or base contacts in the fabrication of back-contact solar cells.

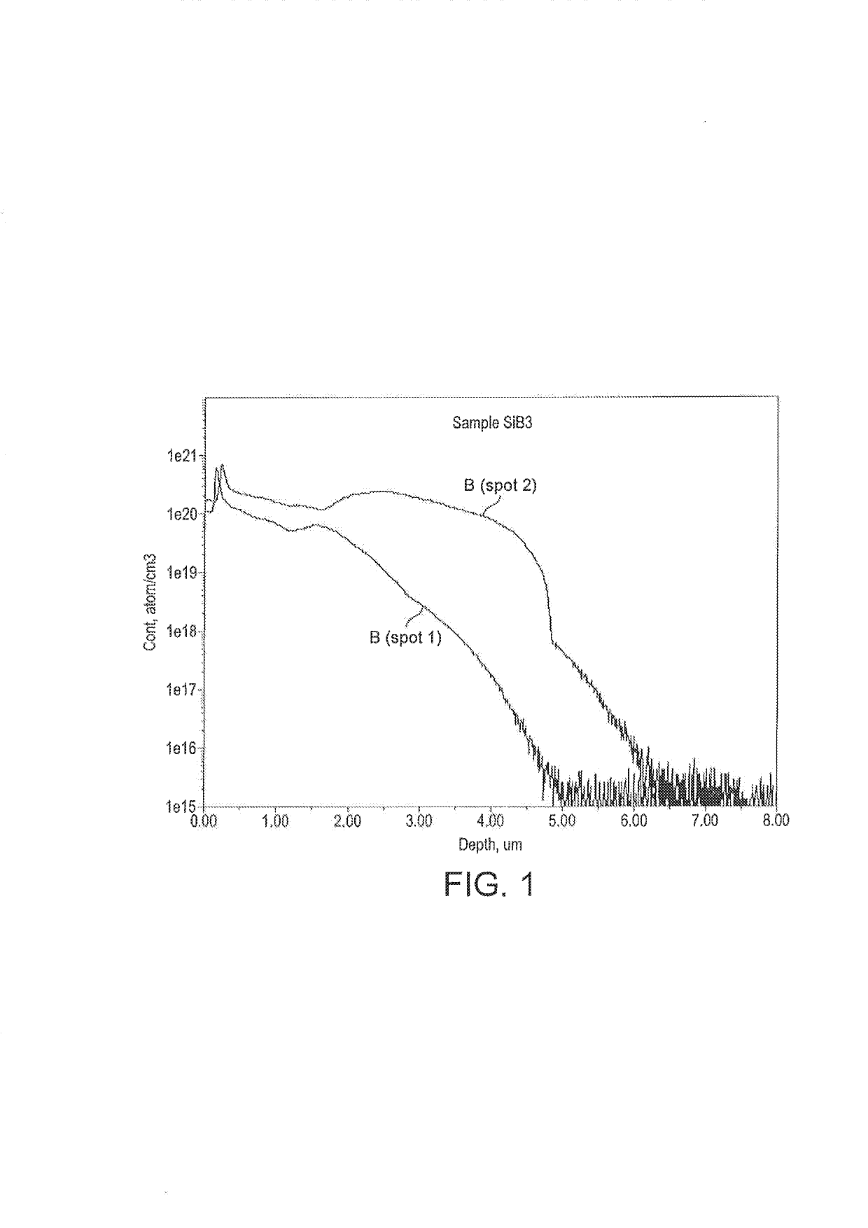

It may be useful to provide specific examples of the various features described herein and then to describe the dopant compositions and the related process steps in relation to the structure described herein. The description then proceeds to more specific results achieved in testing several exemplary implementations with reference to FIGS. 1-4.

### Silicon Material

Silicon powder is produced in large quantities in fluidized bed reactors. The particle size generally ranges from about 100 nm to a few microns. Any appropriate source of Si particulate could be used. In examples of the present exemplary embodiment, the silicon powder may have a particle size such that at least 70% by volume of the particles have a size between 300 and 500 nm. In some examples, larger particles, for example micron-sized particles or larger, may be removed from the silicon powder, for example by decanting or filtering. Si powder is typically intrinsically doped or very lightly doped, additional doping is achieved by adding a dopant to a solution or slurry of Si powder or by mixing a dopant with the Si powder. Any appropriate method may be used to form the Si particulate material suitable for application to the substrate. Silicon powder may be mixed with a non-aqueous solvent, or organic solvent to form a slurry. The organic solvent may include cyclic or chain carbonates, or a mixture thereof. Examples of such solvent mixtures include:

A—ethylene carbonate, dimethyl carbonate and propylene carbonate;

B—ethylene carbonate ethyl methyl carbonate and propylene carbonate

C—ethylene carbonate, diethyl carbonate and propylene carbonate.

The amount of silicon in the solvent may be for example 0.01 to 5 wt % of the organic solvent. U.S. Pat. No. 6,521,375 describes the formation of such slurries in relation to electrolytes in rechargeable lithium batteries. It has been reported (Reber et al. (28^{th} IEEE PVSC)) that an organic solvent mixture of ethanol butanol and a fatty acid (as a dispersing agent) can be used to form slurries containing SiC, Si powder and graphite. US Patent Application No. 2007/0275306 describes forming a silicon-containing slurry for use as an anode material in a lithium battery. Silicon and graphite powder, carbon black and polyvinylidene fluoride were combined in a weight ratio of 75:15:10 and mixed in a mortar. Then N-methylpyrrolidone (NMP) was added to the mixture to obtain a slurry. Similar, or different, methods could be used to form a silicon slurry, for example to be ink-jet or aerosol printed or sprayed in examples.

Dopant

The dopant may be a p- or n-type dopant. The dopant could be a powder or particulate material such as Al, In, Sb, B or Bi, which could be mixed with a metal paste or ink or with a Si powder. The dopant could be a powder or particulate material such as an Sb₂0₃, Al(OH)₃, H3B0₃ or B₂O₃, which could be mixed with a metal paste or ink or with a Si powder. The dopant could be an organometallic molecule which could be mixed with a metal paste or ink or with a Si powder. Examples of materials which can be added as p-type dopants include:
aluminum powder (which would normally include a thin coating of aluminum oxide on the surface of the particles)
aluminum hydroxide acetate (powder) C₄H₇Al0₅
aluminum fluoride (powder) AlF₃.3H₂0
aluminum hydroxide (gel, dried powder) Al(OH)₃
aluminum oxide (powder) Al₂0₃
boron (powder) B
boric anhydride B₂O₃
boric acid H₃BO₃
boron nitride BN

Examples of materials which can be added as n-type dopants include:

antimony metal (powder) Sb

antimony trioxide Sb₂0₃

arsenic (III) oxide (powder) As₂O₃

bismuth citrate (powder) C₆H₅BiO₇

bismuth chloride oxide (powder) BiOCl

phosphorous acid (orthophosphorous acid) H₃PO₃

The dopant may comprise a fine powder for example a powder including one or a mixture of the following:

indium powder (In>=97-99.9999% 20-600 mesh)

bismuth powder (Bi>=99.99% 20-600 mesh)

antimony powder (Sb>=99.5-99.99% 20-600 mesh) where a 600 mesh has hole openings of 301.1 μm.

The dopant may be added to a conductive paste or ink or to a silicon powder in solution. Soluble p-type dopant sources include:

Boron trichloride 10% in methanol

Aluminium chloride solution

Soluble n-type dopant sources include:

Antimony trichloride

Phosphoric acid 85%

Arsenic (III) iodide

In an example, the dopant composition includes a dopant source, silicon powder and PVA (polyvinyl alcohol) as organic solvent. Polyvinyl alcohol has excellent film forming, emulsifying and adhesive properties. It is also resistant to oil, grease and solvent. It is odorless and non-toxic. Another organic solvent that may be used in the dopant composition is ethylene glycol. Examples of doping mixtures for spray coating or aerosol jet printing of dopant compositions for laser-fired contacts include

Mixture 1

Silicon powder, Asl₃, PVA and water

Mixture 2

Silicon powder, BCl₃ in methanol, PVA and water

Mixture 3

Silicon powder, B powder, ethylene glycol and water

Mixture 4

Silicon powder, Sb powder, ethylene glycol and water.

Mixture 5

B powder, ethylene glycol and water

Mixture 6

Sb powder, ethylene glycol and water

Mixture 7

Ag ink, B powder, and water

The compositions of the mixtures can be chosen to achieve the desired viscosity. The amount of dopant material in the mixtures with silicon powder is about from 1 to 50 wt % based on the weight of the silicon powder. The mixtures would be mixed and then, if desired, allowed to settle to separate out larger particles which would then be removed before use of the mixture. The dopant composition can also be formulated as a paste which could be deposited by screen printing, for example. An example of a doping mixture for an antimony paste is: 84 wt % Terpineol, 4 wt % ethyl cellulose and 12 wt % Sb powder. The dopant could also be an organometallic precursor that is added to a silicon or metal powder in formulating a doping ink or paste. In addition, other components such as surfactants or dispersant/wetting agents could be added to the mixtures.

Preparation of Doped Silicon Material

The doped silicon powder may be applied to the substrate in the form of a solution containing the doped powder. In a first example, the doped powder solution is made by adding ethylene glycol as a carrier to the silicon particles and the boron particles. The amount of ethylene glycol in the mixture is adjusted to achieve the viscosity required for the deposition method. In a second example, the silicon powder and boron powder are mixed with a binder including silicon, oxygen and carbon. The amount of binder in the mixture is determined so that adhesion and mechanical durability are adequate for the application and is typically in the range of 5 to 20% of the mixture.

Preparation of the Substrate

In this example, the substrate comprises a silicon wafer. One or more surfaces of the substrate are prepared prior to the application of the doped silicon material, including application of a dielectric passivation layer to a surface of the substrate.

Application of the Doped Silicon Material to a Substrate

In this example, the powder is applied by aerosol jet printing a solution containing the doped powder. In an alternative, a spraying operation can be used with a mask to apply the doped powder to discrete regions of the substrate.

### Laser-Doping

A laser is then used to laser-dope the doped Si powder regions to form emitter or base contacts depending on the type of doped powder applied to the relevant region.

### Fabrication of a Solar Cell

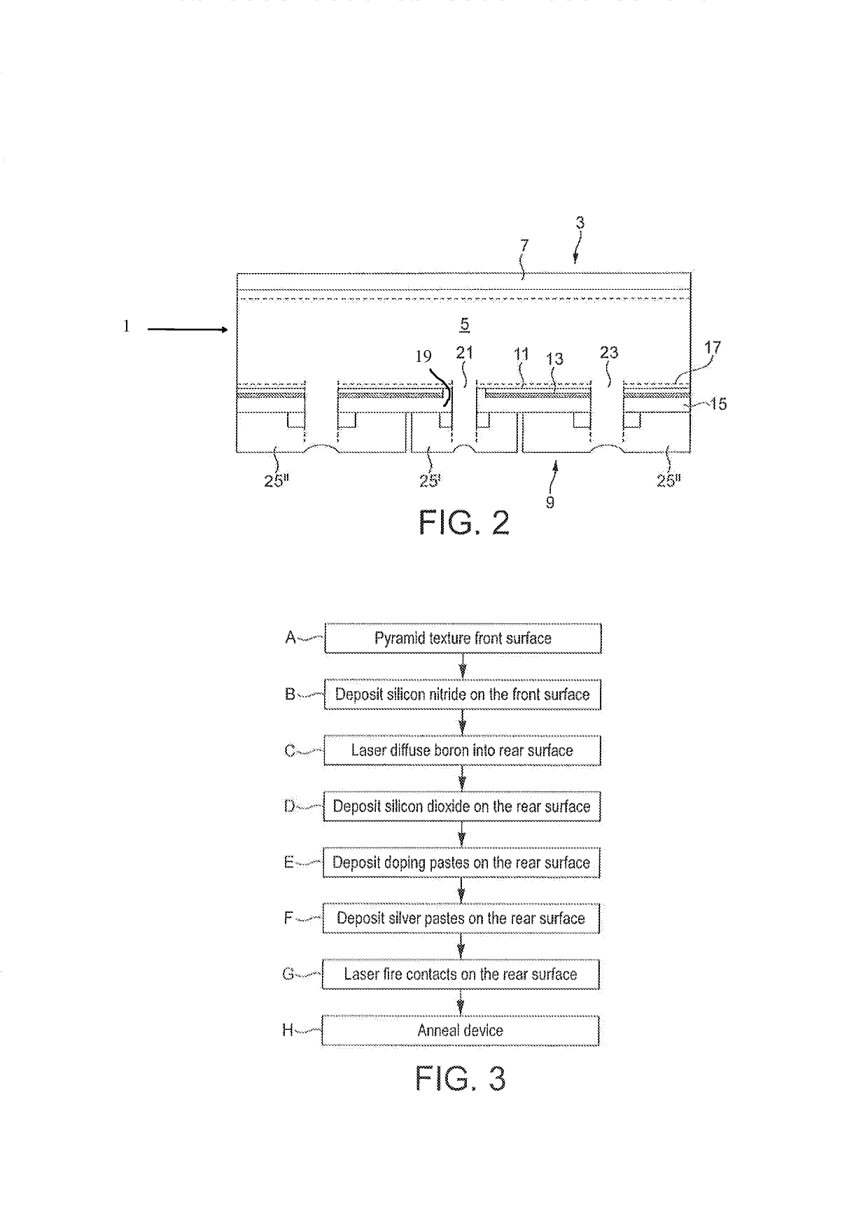

In this example, a back-contact-type cell shown in FIG. 2 is formed. The principles of the method can be applied to the forming of other types of cell, for example other types of solar cell. With reference to the cell 1 shown schematically in FIG. 2, the front surface 3 of the p-type wafer 5 is coated with an antireflection layer 7 of silicon nitride while the rear surface 9 is passivated with a thin layer 11 (having a thickness of about 10 nm in this example) of undoped amorphous silicon (a-Si:H) coated with a phosphorus-doped layer 13 of amorphous silicon (having a thickness of about 20 nm in this example). These layers are overcoated with a silicon oxide layer 15 (having a thickness of about 100 nm in this example).

The doped a-Si:H layer 13 creates an inversion layer 17 in the silicon wafer 5, which will assist in the collection of minority carriers. To prevent leakage (shunting) to the base contacts, an isolation gap 19 is formed around the region where the laser-fired or laser-doped base contact is formed. This isolation gap 19 could be formed for example by laser ablating the a-Si:H layers 11, 13 with a UV ps or fs laser. The base and emitter contacts are formed by depositing the p-type dopant mixture and the n-type dopant mixtures in the appropriate locations and then laser doping to form the p⁺ and n⁺ regions (21, 23 respectively), and then applying interdigitated metal fingers such that one finger pattern 25′ contacts the p⁺ regions and the other metal finger pattern 25″ contacts the n⁺ regions. Alternatively the interdigitated fingers could be deposited over the dopant mixtures and the contacts could be formed by laser firing the metal in the appropriate regions.

Another alternative is to apply doped silver pastes to form the interdigitated fingers, and the contacts could be formed by laser firing the doped silver in the appropriate regions. The fingers that form the n⁺ contacts might contain a silver paste mixed with an antimony trioxide powder (e.g. about 5 wt. % Sb₂0₃ in Ag). The fingers that form the p⁺ contacts might contain a silver paste mixed with a boron powder (e.g. about 0.5 wt. % B in Ag). The solar cell may then be annealed to optimize the contacts, for example for 10 minutes at 300 to 450° C.).

In another example, the doped a-Si:H layer could supply the dopant source for the laser-fired or laser-doped emitter contacts while the base contact is formed using a dopant mixture applied in the appropriate regions as an ink or paste. In this case the dopant level and/or the thickness of the doped a-Si:H could for example be selected to optimize the laser-processed emitter contacts. Other passivation layers such as aluminum oxide, silicon dioxide, silicon carbide can also be used in forming laser-processed solar cells. For back-contact cells, the thickness of the rear surface passivation layer or layers may be for example from about 80 to 150 nm.

In the example discussed above and illustrated in FIG. 2, both p- and n-type dopant components are applied. These can be applied together, or in any appropriate order. In this example, the p-type dopant is applied first. A first dopant composition, including a p-type dopant (e.g. an ink comprising about 2 wt. % of boron nanoparticles in ethylene glycol), is applied to regions of the passivation layer. In this example, the first dopant composition is applied locally using an aerosol jet printer, an inkjet printer or a screen printer to form an array of applied dopant composition regions including the first type of dopant. A second dopant composition, including an n-type dopant (e.g. an ink comprising about 5 wt. % of antimony trioxide nanoparticles in ethylene glycol) is subsequently applied to regions of the passivation layer to form a second array of applied dopant regions including the second type of dopant. The second array is applied using an aerosol jet printer, an inkjet printer or a screen printer to print discrete regions of the second dopant composition on the passivation layer. In this example, two arrays of doped silicon material, of opposite doping type are applied to the surface to form an alternating array of n-doped and p-doped regions.

During the printing operation, the substrate is supported on a platen which is heated to about 150 degrees C. The raised temperature assists the driving off of solvents and/or other carriers in the applied dopant compositions. A high speed scanning laser is then used to laser-dope the appropriate regions to form alternating arrays of emitter and base contacts using a pulsed Nd:YAG laser operating at a wavelength of 532 nm and with a pulse duration of about 10 to 200 ns and with a fluence of about 1.5 to 4 J/cm². The laser beam used is approximately 100 microns in diameter and the laser can be scanned at speeds up to 10 m/s. Once the laser doping procedure is complete, conductive elements are then formed on the arrays of contacts. For example, interdigitated fingers of Ag or other conductive material are applied, for example printed, over the alternative arrays of laser-fired contacts. As appropriate, an annealing operation can be carried out on the applied conductive material.

Example of Forming a p-Type Contact

A dopant ink composition including Si and B particles was spray deposited onto a substrate comprising a Si wafer passivated with a 50 nm layer of a-Si:H. The ink composition comprised Si particles of approximately 0.4 microns in diameter, and B particles approximately 1 micron in diameter in a solution of ethylene glycol containing a poly(ethylene glycol) binder with an average molecular weight of 300. An approximately 0.5 micron thick layer of Ag was then e-beam deposited onto the substrate. The laser-fired contacts were formed at the region of deposition of the dopant ink composition using a Nd-YAG laser (1064 nm wavelength) operating in a gated CW, five pulse mode with a 90% duty cycle. Each of the gated CW pulses last about 340 ns (FWHM) and are 100 1.1,S apart. The energy density of the second or later pulses is about from 7 to 10×10⁹ W/m² (the CW mode is on for 90 1.is and the laser is off for 10 ps for 90% duty cycle). The energy density of the first pulse in this example is significantly less than that in subsequent pulses. The total energy in each of the subsequent pulses is about 3 J/cm² while that in the CW mode (90% duty cycle) is about 20 J/cm². Higher power densities are thought to be required with laser-fired contacts as compared to laser-doped contacts due to the higher reflectivity of the metal.

The laser-fired contacts exhibited craters with diameters of about 100 microns. A Secondary Ion Mass Spectrometry (SIMS) analysis was carried out in a central region of about 60 micron diameter in the crater. The concentration of B at different depths of the substrate was measured and is shown in FIG. 1. The results show that there is significant penetration of the B into the substrate for both of the samples tested (B(spot 1) and B(spot 2)). Without wishing to be bound by any particular theory, the depth of the boron diffusion suggests that the silicon of the substrate is molten during most of the gated CW, 5 pulse mode process time (about 400 us).

Example of Forming Contact Region Using Dopant Composition Comprising Electrically Conductive Material.

As discussed above, where an electrically conductive material, for example a metal, is added to the dopant composition before laser processing the it can be possible for the contact to be formed using fewer steps that a method in which an applied dopant is first processed on the substrate prior to the separate application of the electrically conductive material. A method similar to that described above may be used to form doped regions in a substrate. In this example however a dopant composition including electrically conductive material is used.

Examples of n-type dopant compositions include:
A mixture of 1.0 gram of Si powder, 0.88 grains of antimony powder and 40 ml of ethylene glycol.
A mixture where the mixture listed above was mixed with an equal volume of commercial Ag ink.
A mixture of 0.88 grams of antimony powder ink mixed with 40 ml of ethylene glycol.

Examples of p-type dopant compositions include:
A mixture of 1.5 grams of a fine silver powder with 15 ml of ethylene glycol containing 0.2 grams of a mixture of silicon powder and boron powder ink (the boron content is 13 wt. % of the powder mixture).
A mixture of 1.0 gram of Si powder and 0.13 grams of boron powder mixed with 40 ml of ethylene glycol.
A mixture of 0.13 grams of boron powder mixed with 40 ml of ethylene glycol.
A mixture where the mixture listed above was mixed with a volume of Ag ink that was 5 times larger.

The ink compositions are mixed and applied to a surface of a passivated Si wafer and laser firing is carried out.

In view of the ink compositions including a fine Si powder which can form a loose porous ink layer on the substrate surface, the method may include the step of washing loose ink before deposition of the metal contact. FIG. 3 shows a process flow for an example in which laser doping is used to form a back-contact solar cell in the following steps:
A—A texture is applied to a front surface of an n-type silicon wafer. In this case a pyramidal texture is formed by etching (100) silicon in potassium hydroxide.

B—Silicon nitride is deposited on the front surface to act as an antireflection coating.
C—An ink containing boron is sprayed onto the rear surface of the wafer and laser doping is performed over most of the wafer to provide a shallow emitter. The base isolation regions are formed by not applying laser doping to those regions. After the shallow emitter is formed, the rear surface is cleaned to remove any residual boron ink.
D—Silicon dioxide is deposited on the rear surface to act as a dielectric passivation layer. E—Both p-type and n-type doping pastes are deposited in the appropriate regions on the rear surface.
F—Silver paste is applied as an interdigitated electrode pattern on the rear surface.
G—The n⁺ base contacts and the p⁺ emitter contacts are formed by laser firing the silver through the doping pastes.
H—The cell is annealed for 5 minutes at 350° C.

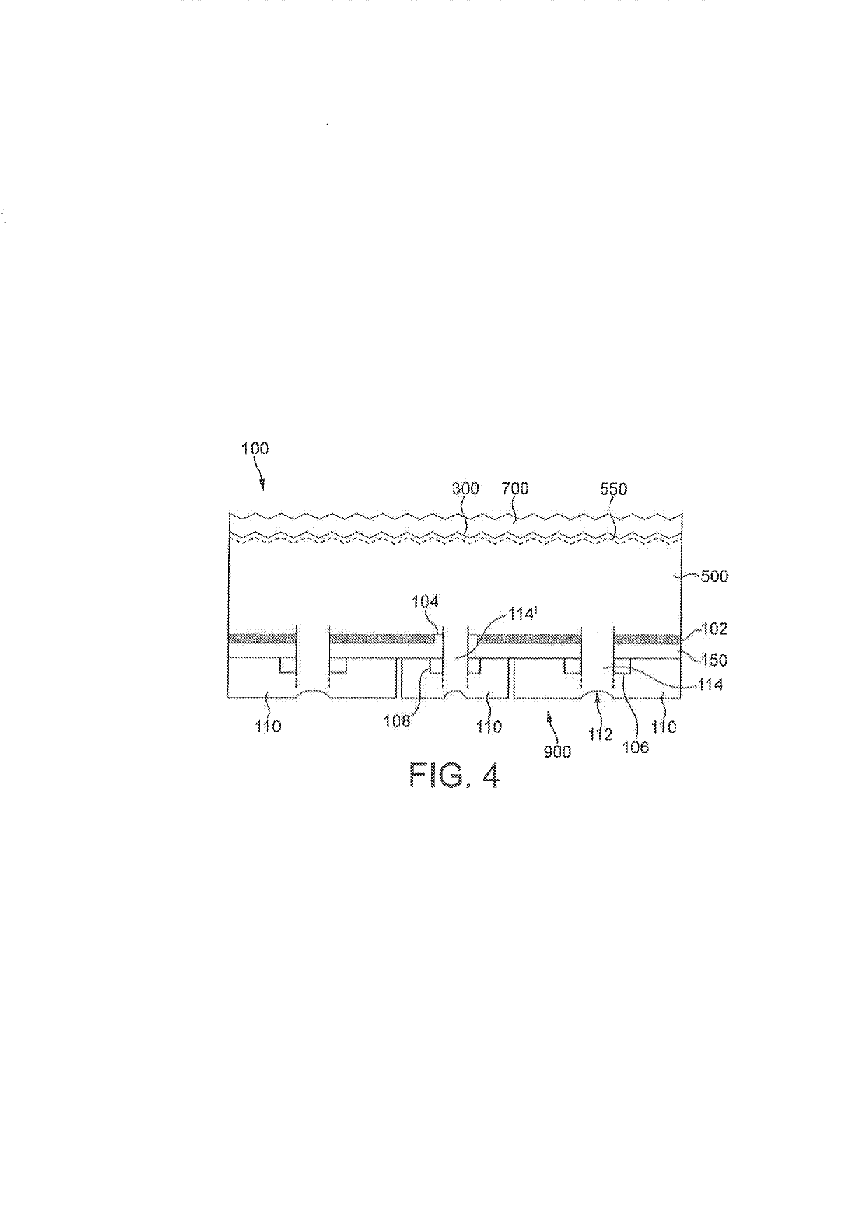

FIG. 4 shows a schematic sectional view of an example of an array of contacts formed by the method described above in relation to FIG. 3. FIG. 4 shows a cell 100 including an n-type silicon wafer 500. The front surface 300 of the wafer 500 has a pyramidal texture 550 formed by the etching step. The front surface 300 is coated with an antireflection layer 700 of silicon nitride. The diffusion of the boron into the rear surface 900 using laser doping forms a boron diffused layer 102 which provides a shallow emitter. The regions 104 in which the shallow emitter is not formed provide electrical isolation gap to the base contacts. A layer of silicon dioxide 150 extends over the boron diffused layer 102 and the isolation regions 104 on the rear surface 900. The cell further includes the regions of the p⁺ doping paste 106 and the n⁺ doping paste 108 which have been applied to regions of the silicon oxide layer 150. Regions of silver paste 110 extend over the p⁺ and n⁺ doping paste regions 106 and 108.

It can be seen that the laser firing of the silver paste regions 110 has fired silver material, and doping paste 106, 108 through the silicon dioxide layer 150 to form the contact. For example in the region where p⁺ doping paste 106 has been applied, the laser firing technique has fired silver material from a laser firing region 112. Furthermore it can be seen that the p⁺ doping paste 106 and silver from the silver paste region 110 has been fired through the silicon dioxide layer 150 to form the contact. In a laser fired region of the doping paste 114, it can be seen that the doping material 106 has moved through the silicon oxide layer 150. In a laser fired region of the doping paste 114′, it can be seen that the doping material 108 has moved through the silicon oxide layer 150. Another example of forming a back contact cell involves using thermal diffusion of boron in an n-type wafer to form a shallow emitter. In this case the isolation region around the base contacts could be formed by laser ablation with a ps or fs laser or by etching away the boron diffused region locally or by masking the isolation regions with a boron diffusion barrier prior to the thermal diffusion. After forming the shallow emitter and the isolation regions for the base contacts, one would then deposit silicon nitride on the textured front surface and silicon dioxide on the non-textured rear surface. The localized n⁺ and p⁺ contacts could then be formed by laser doping or laser firing as described above.

While a number of exemplary aspects and embodiments have been discussed above, those of skill in the art will recognize certain modifications, permutations, additions, and sub-combinations thereof. It is therefore intended that the following appended claims and claims hereafter introduced are interpreted to include modifications, permutations, additions, and sub-combinations to the exemplary aspects and embodiments discussed above as are within their true spirit and scope.

1. A dopant composition comprising a particulate dopant component and a liquid or paste component.

2. A dopant composition according to claim 1, including a semiconductor component.

3. A dopant composition according to claim 2, wherein the dopant composition comprises a particulate silicon component.

4. A dopant composition according to claim 1, wherein the dopant composition further includes a conductive material.

5. A dopant composition according to claim 1, wherein the liquid or paste component includes one or more of water and an organic solvent.

6. A dopant composition according to claim 5, wherein the organic solvent comprises one or more of polyvinylalcohol, ethylene glycol or ethyl cellulose.

7. A dopant composition according to claim 1 wherein the average primary particle size of particles of the dopant composition is less than 600 nm.

8. A dopant composition according to claim 1 wherein the average secondary particle size of particles of the dopant composition is less than 2 microns.

9. A dopant composition according to claim 1 wherein the average primary particle size of particles of the dopant composition is between about 10 and 100 nm.

10. A dopant composition according to claim 1 wherein the dopant composition includes at least 50% by weight of the dopant.

11. A dopant composition according to claim 1, wherein the dopant component includes a source of a Group V or Group III element.

12. A dopant composition according to claim 1, further including one or more of a surfactant, a dispersant and a wetting agent.

13. A dopant composition according to claim 1, wherein the dopant composition is in the form of an ink or a paste.

14. A method of forming a doped region in a substrate in a semiconductor material, comprising the steps of:
applying a dopant composition to a region of a dielectric layer, wherein the dopant composition includes a particulate component; and
treating the applied dopant composition with radiation to form a doped region in a substrate in the semiconductor material, where the substrate includes a dielectric layer over at least a portion of the semiconductor material.

15. A method according to claim 14, wherein the dopant composition comprises a dopant particulate component.

16. A method according to claim 14, wherein the dopant composition comprises a mixture of a dopant material and a particulate material.

17. The method of claim 14, wherein the step of treating with radiation comprises applying laser radiation to the applied dopant composition.

18. The method of claim 14, wherein the dopant composition comprises a dopant component and a conductive material component.

19. The method of claim 18, wherein the dopant component includes an electrically conductive material component.

20. The method of claim 19, wherein the electrically conductive material component forms an electrical contact to the doped region of the substrate.

21. The method of claim 18, wherein the conductive material component comprises a metal component.

22. The method of claim 21, wherein the metal component includes Ag, Al, Ni, Cu or any combination thereof.

23. The method of claim 18, wherein the dopant composition further comprises a binder.

24. The method of claim 14, wherein the dopant composition comprises the dopant substantially alone in powder form, where the dopant is selected from a group consisting of boron, aluminum, indium, antimony or bismuth.

25. The method of claim 14, wherein the dopant composition comprises a compound including boric acid, boron anhydride, aluminum hydroxide, antimony trioxide and any other combinations thereof.

26. The method of claim 28, wherein the dopant composition further comprises a liquid carrier medium, where the liquid carrier medium is selected from a group consisting of water, alcohol, ethylene glycol, or any combination thereof.

27. The method of claim 14, wherein the dopant composition is printed onto the substrate.

28. The method of claim 14, wherein the dopant composition is applied to a plurality of discrete regions on the substrate.

29. The method of claim 18, wherein the dopant component comprise n-type or p-type dopants.

30. The method of claim 14, wherein the doped region of the semiconductor material forms a base or emitter contact.

31. A method of forming two or more doped regions on a substrate in a semiconductor material, comprising the steps of:
applying a first dopant composition to a first region of the substrate;
applying a second dopant composition to a second region of the substrate; and
treating the first and second regions to form first and second arrays of doped regions in the semiconducting material, where the substrate includes a dielectric layer over at least a portion of the semiconductor material.

32. A method of claim 53, wherein the first dopant composition is applied to a plurality of first regions to form a first array of first dopant regions on the substrate; and applying the second dopant composition to a plurality of second regions to form a second array of second dopant regions on the substrate.
